(19) United States
(12) Patent Application Publication
(10) Pub. No.: US 2025/0006666 A1
(43) Pub. Date: Jan. 2, 2025

(54) MICROSTRIP ROUTING ON EMBEDDED HIGH-K DIELECTRIC

(71) Applicant: Intel Corporation, Santa Clara, CA (US)

(72) Inventors: Jiun Hann Sir, Gelugor (MY); Poh Boon Khoo, Perai (MY)

(73) Assignee: Intel Corporation, Santa Clara, CA (US)

(21) Appl. No.: 18/215,480

(22) Filed: Jun. 28, 2023

(51) Int. Cl. H01L 23/66; H01P 3/08; H01P 11/00

(52) U.S. Cl. CPC H01L 23/66; H01P 3/081; H01P 11/003; H01L 2223/6627

(57) ABSTRACT

An integrated circuit (IC) device includes an IC die on a substrate, and the substrate includes a group of conductive lines between a high-permittivity dielectric layer and a low-permittivity dielectric layer, with a ground plane separated from the conductive lines by either the high- or low-permittivity dielectric layer. The substrate may include other low-permittivity dielectric layers. The substrate may include other groups of conductive lines between ground planes. The high-permittivity dielectric layer may be within a low-permittivity dielectric core layer.

### BACKGROUND

Integrated circuit (IC) substrates are growing increasingly complex, for example, having many layers, while industry factors push for substrates with fewer layers. Increased component counts and functionalities increase routing complexities, but demands for reduced form factors (including in mobile systems) limit substrate sizes, including substrate heights. Cost pressures and supply-chain constraints encourage simplifying substrate stack-ups.

Improved structures, materials, and methods are needed to reduce layer counts in IC substrates while maintaining (or improving) IC system performance, such as signal integrity.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, and 1D illustrate a substrate having conductors adjacent dielectric layers and a ground plane in a microstrip structure, in accordance with some embodiments;

FIGS. 2A, 2B, 2C, and 2D illustrate substrates in an integrated circuit (IC) device having conductors adjacent dielectric layers and a ground plane in a microstrip structure, in accordance with some embodiments;

FIGS. 3A and 3B illustrate plan views of an IC device, including adjacent layers of a multilayer substrate having groups of conductors in a dielectric layer in cutouts of ground planes and over a dielectric layer, in accordance with some embodiments;

FIG. 4 is a flow chart of methods for forming a substrate with conductors along an interface of lower- and higher-permittivity dielectric layers, in accordance with some embodiments;

FIGS. 5A, 5B, 5C, 5D, 5E, 5F, and 5G illustrate cross-sectional profile views of a substrate with a high-permittivity dielectric layer adjacent conductors and conventional dielectric layers, at various stages of manufacture, in accordance with some embodiments;

FIG. 6 illustrates a diagram of an example data server machine employing an IC device having signal lines between higher and lower-permittivity dielectric layers in a microstrip structure, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to reduce the cost, complexity, and layer count, and improve the performance, of integrated circuit (IC) device substrates. Substrates can add complexity and cost to IC systems. By reducing substrate complexity and layer counts, IC device manufacturing costs and other constraints may be reduced. Besides reducing manufacturing times and costs, reduced layer counts may allow for alternate or additional substrate suppliers. Reduced manufacturing times and costs, and additional substrate suppliers, may provide manufacturing and other supply chain flexibilities.

Substrates in IC systems may be made with fewer layers by using a microstrip structure rather than a stripline structure for signal lines. A microstrip structure is commonly used on substrate surfaces with an exposed signal line having air as a dielectric on a side of the signal line opposite a single ground plane. The absence of an additional ground layer in a stripline structure may be compensated for by using a high-permittivity (“high-K”) dielectric adjacent the signal line(s) rather than air, a low-permittivity (“low-K”) dielectric material. This high-K dielectric in a microstrip structure can be employed in internal substrate layers, e.g., core layers of IC package substrates. For example, a high-K dielectric can replace a layer of a conventional dielectric on the core side of signal lines (or other conductors), e.g., with one or more conductors and the conventional dielectric between the high-K dielectric and a ground layer in a multilayer package (or other) substrate. Such a high-K dielectric can suppress crosstalk between adjacent signal lines by increasing capacitance between signal lines and adjacent structures (including other signal lines). This mutual capacitance or capacitive coupling to suppress crosstalk is especially advantageous in high-frequency applications and where strict control of signal timing is needed, such as DDR RAM (double data rate random-access memory) applications. DDR and other RAM applications may also benefit as crosstalk suppression may be especially valuable and necessary for these and other applications having signals propagating along lines packed closely together and with long parallel stretches (e.g., data buses).

Crosstalk, such as far-end crosstalk (FEXT), which may not be problematic in a symmetric stripline structure, may need to be addressed in a substrate stack with fewer layers and without symmetric ground planes on both sides of conductor lines, e.g., signal buses. This increased capacitance beneficially introduced by a high-K dielectric material counters the inductances of, e.g., relatively long, parallel traces (such as bus lines) and more tightly confines electric fields. A dielectric layer's permittivity and thickness can be adjusted to balance or otherwise adjust various parameters of a signal line, such as impedance, propagation speed, and crosstalk.

The structures and methods described enable reduced substrate height, complexity, cost, and manufacturing time. A microstrip structure with lower- and higher-permittivity dielectric layers may minimize crosstalk in a substrate with a reduced layer count.

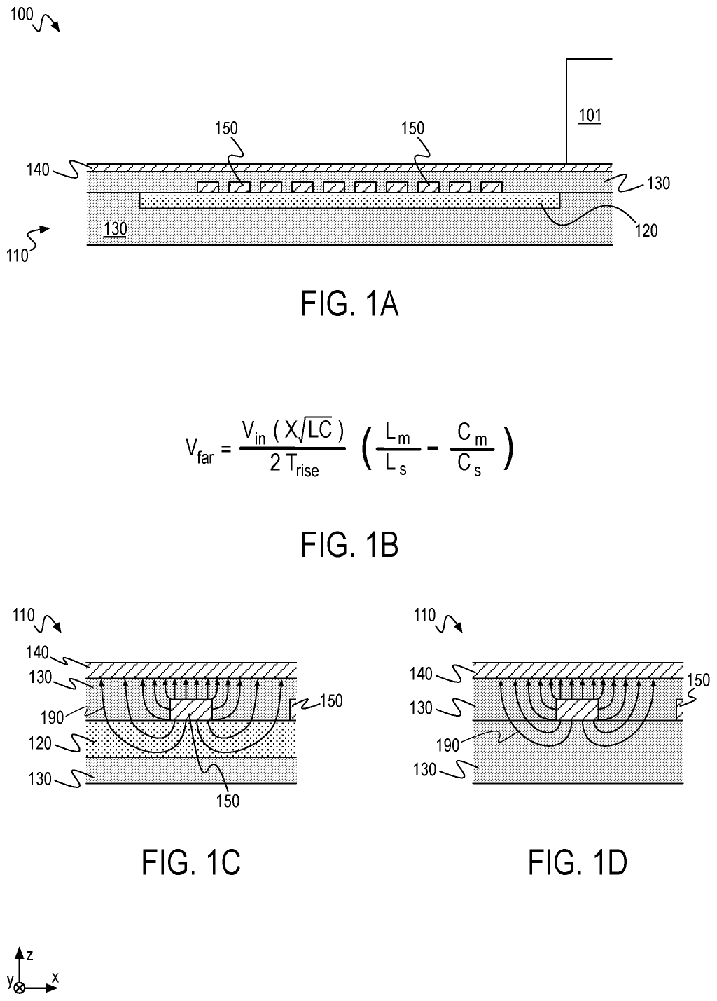

FIGS. 1A, 1B, 1C, and 1D illustrate a substrate 110 having conductors 150 adjacent dielectric layers 120, 130 and a ground plane 140 in a microstrip structure, in accordance with some embodiments. Conductors 150 may be parallel traces or lines (running in the y direction), for example, in one or more data buses, in a microstrip structure with conventional dielectric layer 130 between conductors 150 and a single ground plane 140. A high-K dielectric layer 120 may be employed adjacent conductors 150 to reduce crosstalk between adjacent conductors 150 in the bus and to improve confinement of electrostatic and magnetic fields around conductors 150. In various embodiments, high-K dielectrics in accordance with this disclosure may include titanium (Ti) oxides (e.g., TiO₂), hafnium (Hf) oxides (e.g., HfO₂), and/or zirconium (Zr) oxides (e.g., ZrO₂). As such, in accordance with this disclosure, a high-K dielectric material or layer 120 may have at least twice as much titanium, hafnium, and/or zirconium as a dielectric material or layer 130 that is not high-K. For example, a high-K dielectric material or layer 120 may have a concentration of titanium, hafnium, and/or zirconium that is at least twice a concentration of titanium, hafnium, and/or zirconium in a dielectric material or layer 130 that is not high-K. A common microstrip structure would have air (a low-K dielectric) opposite ground plane 140 (with conventional dielectric layer 130 (e.g., silicon (Si) and/or aluminum (Al) oxide) and exposed conductors 150 between the air and ground plane 140). Substrate 110 is in IC device 100, with IC die 101 on and coupled to substrate 110.

FIG. 1A shows substrate 110 microstrip structure instead having high-K dielectric layer 120 opposite ground plane 140 with conventional dielectric layer 130 and conductors 150 between layer 120 and ground plane 140. The group of conductors 150 is at an interface of the upper dielectric layer 130 and dielectric layer 120, and high-K dielectric layer 120 is between conductors 150 and lower dielectric layer 130. High-K dielectric layer 120 is between upper and lower dielectric layers 130. Ground plane 140 is adjacent dielectric layer 120 and upper dielectric layer 130, and upper dielectric layer 130 is between, and separates, ground plane 140 and high-K dielectric layer 120. Conductors 150 may be parallel lines (parallel to each other and parallel to, e.g., ground plane 140) that each correspond to a bit in a data word. The group of conductors 150 may have four, eight, 16, or more conductors 150 (e.g., corresponding to a word size), but may include more or fewer conductors 150 as well. In the example of FIG. 1A, the group of conductors 150 is within upper dielectric layer 130 and in contact with high-K dielectric layer 120.

High-K dielectric layer 120 is of a dielectric material having a permittivity (or relative permittivity (e.g., relative to vacuum permittivity) or dielectric constant) greater than the permittivity (or permittivities) of the dielectric material(s) of upper and lower dielectric layers 130. Dielectric layers 130 may have a single, same dielectric constant or permittivity, or various permittivities, but high-K dielectric layer 120 has a dielectric constant or permittivity greater than the permittivity or various permittivities. For example, in the example of FIG. 1A, upper and lower dielectric layers 130 have a same or similar composition and relative permittivity (less than the relative permittivity of high-K dielectric layer 120). In many embodiments, various layers 130 have different compositions, but substantially equal permittivities. For example, some layers 130 are build-up dielectric layers with a different composition than, but a permittivity substantially equal to that of, one or more core dielectric layers 130, and all layers 130 with permittivities less than a permittivity of high-K dielectric layer 120. In some embodiments, layer(s) 120 and/or 130 include multiple dielectric materials, e.g., of various permittivities, but with the net effect that the permittivity of high-K dielectric layer 120 is greater than the permittivity of dielectric layer(s) 130. The term “permittivity” may be used interchangeably with the terms “relative permittivity” and “dielectric constant” to refer to a measure of the electric polarizability of a dielectric material or dielectric layer, which relates to the dielectric material's ability to store energy. The material(s) (and so permittivity), location, and thickness of high-K dielectric layer 120 may be controlled to set the various parameters (e.g., electrical characteristics) of layer 120, conductors 150, etc.

FIG. 1B illustrates an equation relating various parameters affecting crosstalk, specifically FEXT. The received or coupled voltage V_{far} in the victim line is larger or increases for a larger input signal voltage Vᵢₙ, a faster transition (with a shorter rise time Tᵣᵢₛₑ), and a longer coupled routing length X. The mutual and self inductances (Lₘ and Lₛ, respectively) and capacitances (Cₘ and Cₛ, respectively) are key parameters to suppress the FEXT. The coupled voltage V_{far} can be minimized by offsetting the inductive and capacitive coupling terms. That is, the coupled voltage V_{far} can be zeroed out by matching the capacitive term (mutual capacitance Cₘ divided by self capacitance Cₛ) to the inductive term (mutual inductances Lₘ divided by self inductance Lₛ). This is the case in an ideal stripline structure (e.g., with signal conductors centered between symmetric ground planes and in a homogenous dielectric), but such a cancellation (or minimization) in the proposed microstrip structure may require an adjusting of the mutual and self capacitances Cₘ, Cₛ. With long coupled routing lengths X (e.g., in parallel data buses), correspondingly high mutual inductances Lₘ, and high frequencies (e.g., in DDR applications), the mutual capacitance Cₘ for most signal lines will likely need to be increased (and increased more than the self capacitance Cₛ).

FIG. 1C shows an embodiment with high-K dielectric layer 120 adjacent conductors 150 and correspondingly elevated mutual and self capacitances Cₘ, Cₛ, but with a mutual capacitance Cₘ elevated to a greater extent. The paths and relative spacings of field lines 190 (including relative to field lines 190 in FIG. 1D) illustrate the effects of the different permittivities of dielectric layers 120, 130. The self capacitance Cₛ for a given conductor is impacted by the permittivities of the dielectrics both away from and between conductor 150 and ground plane 140, both layers 120, 130. However, the self capacitance Cₛ for a given conductor will be dominated by the permittivity of layer 130 between conductor 150 and ground plane 140. The mutual capacitances Cₘ of both conductors 150 will be increased by the higher permittivity of layer 120 and will be influenced, but not dominated, by the permittivity between conductors 150 and ground plane 140. These combined effects will increase the capacitive term (mutual capacitance Cₘ divided by self capacitance Cₛ) and act to minimize the coupled voltage V_{far} in the FEXT equation. This effect is consistent with the increased range of field lines 190 in high-K dielectric layer 120, which shows how mutual capacitances Cₘ between adjacent conductors 150 may increase (and cancel inductive coupling between adjacent conductors 150, which may be significant conductors 150 adjacent and parallel for relatively long stretches, such as signal buses). Capacitances Cₘ, Cₛ could also be adjusted in other ways, e.g., by changing the dimensions between conductors 150 and ground plane 140, but the deployment of layer 120 allows for controlling capacitances Cₘ, Cₛ independently of the dimensions of substrate 110. The deployment of layer 120 allows for maintaining (and even reducing) substrate 110 dimensions, which may assist in maintaining key dimensions for requisite electrical isolation, manufacturing tolerances, etc.

The crosstalk-suppressing effect of this higher permittivity dielectric layer 120 can be tuned by adjusting pertinent features of layer 120. For example, the higher permittivity can be increased or decreased to minimize the coupled voltage V_{far}. In some embodiments, dielectric layers 130 have a relative permittivity with a magnitude of five or less. For example, dielectric layers 130 may have a relative permittivity of magnitude less than four. In some embodiments, high-K layer 120 has a relative permittivity of 5 or more. For example, high-K layer 120 has a relative permittivity of 7 or more. Higher permittivities may enable a thinner high-K dielectric layer 120. In some embodiments, high-K layer 120 has a relative permittivity of 9 or more. A greater thickness of high-K dielectric layer 120 may be deployed to increase the effect of the higher permittivity, and a lesser thickness of high-K dielectric layer 120 may be deployed to limit the effect of the higher permittivity. In some embodiments, high-K layer 120 (and/or dielectric layers 130) have a thickness of 15 μm or less. In some embodiments, high-K layer 120 and/or dielectric layers 130 have a thickness of 20 μm or more. A higher-K or thicker layer 120 may be advantageous for higher frequency applications, for example, or for longer or tighter parallel buses (e.g., with a greater coupled routing length X or high mutual inductance Lₘ). The effect of high-K layer 120 on the capacitive term in the FEXT equation can also be set differently by deploying high-K layer 120 differently positionally, e.g., relative to conductors 150 and ground plane 140. For example, deploying high-K dielectric layer 120 between conductors 150 and ground plane 140 (or with some of each of layers 120, 130 between conductors 150 and ground plane 140) will have corresponding effects on mutual and self capacitances Cₘ, Cₛ, as described.

Adjusting pertinent features of layer 120 may provide an additional degree of freedom for controlling parameters already described, as well as others. For example, employing a higher permittivity in high-K dielectric layer 120 may increase the mutual capacitances between adjacent conductors 150, which may reduce the crosstalk (e.g., FEXT) between, and increase the characteristic impedance (Zₒ) of, parallel conductors 150. The thickness of high-K dielectric layer 120 may also be adjusted to have similar effects. The thickness of layers 120, 130 may be adjusted in coordination to optimize these and other various parameters of conductors 150, such as propagation constant, routing density, etc.

FIG. 1D illustrates conductors 150 without high-K dielectric layer 120, e.g., elsewhere in substrate 110, and with field lines 190 propagating less far from ground plane 140 and conductors 150 (relative to field lines 190 in FIG. 1C), which will have less of a canceling effect of inductive coupling and result in more crosstalk (relative to conductors 150 adjacent high-K dielectric layer 120 in FIG. 1C).

Returning to FIG. 1A, substrate 110 in IC device 100 is coupled to IC die 101 and may be a package substrate 110. A microstrip structure employing high-K layer 120 may be deployed in other substrate types, e.g., motherboards and other printed circuit boards (PCBs) coupled to one or more IC dies or IC packages. Substrate 110 is a planar platform and may be of any suitable structure and material(s), for example, any sufficiently insulating material or materials, e.g., in dielectric layers 130. For example, substrate 110 (and layers 120, 130) may include one or more organic materials, such as a plastic. In many embodiments, at least one of layers 120, 130 is or includes a layer of resin-impregnated glass fiber or cloth (e.g., a “prepreg” layer). One or both of layers 120, 130 may be or include a laminate, which may include a glass-weave core and resin. In some embodiments, substrate 110 and layers 120 and/or 130 include inorganic materials, including ceramic materials, silicon, or (substantially monolithic) glass, which may have advantages, such as higher thermal conductivity, higher strength and stiffness, and a lower propensity for absorbing moisture (all relative to organic substrate materials). In some such embodiments, substrate 110 has uniformity or isotropic advantages relative to a glass weave or other heterogenous structure.

Although a line is shown between adjacent layers 130 (e.g., in FIG. 1A, on either side of layer 120), adjacent layers 130 may be of the same material and may be substantially continuous with little or no discernible interface or other border between adjacent levels in substrate 110. In some embodiments, adjacent layers 130 may have different compositions, e.g., between a core dielectric layer 130 and other layers 130. Other dielectric layers 130 may be outer layers 130 on one or both sides of a core dielectric layer 130. In some embodiments, an interface may be discernible between adjacent layers 130, even of the same material. In some such embodiments, the interface may include dielectric materials similar or the same as in dielectric layer 130. In some embodiments, the interface may include an additional material. In some embodiments, conductors 150 may be within and under a single layer 130 (e.g., as in the example of FIG. 1A, with that same layer 130 over and lateral to conductors 150, over layer 120). In some embodiments, conductors 150 may be within a first layer 130 and under (and in contact with) a second distinct layer 130.

In some embodiments, as in the example of FIG. 1A, conventional, lower dielectric layer 130 comprises a cavity (or other region in which the material of dielectric layer 130 is absent), high-K dielectric layer 120 is in the cavity, and an upper surface of high-K dielectric layer 120 is substantially coplanar with an upper surface of lower dielectric layer 130. A lower surface of high-K dielectric layer 120 is in contact with a recessed surface of lower dielectric layer 130. Upper dielectric layer 130 is in contact with lower dielectric layer 130, e.g., on either side of high-K layer 120. Such a structure may allow for minimal use of high-K material and for localized placement of high-K layer 120, e.g., only adjacent a bus of conductors 150. Such a structure may be achieved by multiple means, for example, employing a subtractive process where a cavity is hollowed out of lower dielectric layer 130, and a high-K material is formed in the cavity to form high-K dielectric layer 120. In some embodiments, high-K dielectric layer 120 is over conventional dielectric layer 130 over substantially the same areas or footprints, e.g., with vertically aligned perimeters. In some embodiments, high-K dielectric layer 120 is over conventional dielectric layer 130 over the entirety of substrate 110.

High-K dielectric layer 120 may include any suitable material(s). Various laminates, ceramics, resins, or polymers may be employed in one or both of layers 120, 130, and the permittivities (and other material properties) may be different in the different layers 120, 130 (e.g., tuned or adjusted) due to differences in, for example, compositions, concentrations, doping profiles, or other materials properties. Some materials may be present in various concentrations in both layers 120, 130. For example, in some embodiments, layers 120, 130 include a same polymer and a same filler (such as ceramic particles) interspersed in the polymer, but high-K dielectric layer 120 includes a higher concentration of the filler interspersed in the polymer. High-K dielectric layer 120 may utilize any suitable material(s), including ceramic materials, such as oxides of various metals, including hafnium, titanium, zirconium, etc. High-K materials (such as metal oxides) in layer 120 may include dopants, such as magnesium (Mg), yttrium (Y), calcium (Ca), and cerium (Ce) (e.g., in oxides, such as MgO, Y₂O₃, CaO, and Ce₂O₃). In some embodiments, layers 120, 130 both include laminates, but of different materials. In some embodiments, layers 120, 130 both include one or more ceramics, but of different materials. In some embodiments, substrate 110 includes one or more layers 130 of conventional laminate(s), but high-K dielectric layer 120 is of a higher-permittivity material (such as a composite of ceramic nanoparticles in a polymer matrix) over or within a lower-permittivity layer 130. In some embodiments, a high-K dielectric material or layer 120 has a ceramic (or ceramic particle) concentration in a polymer that is at least twice a ceramic (or ceramic particle) concentration in a dielectric material or layer 130 that is not high-K. In some embodiments, a high-K dielectric material or layer 120 has a dopant concentration that is at least twice a dopant concentration in a dielectric material or layer 130 that is not high-K. In some embodiments, a high-K dielectric material or layer 120 has a concentration of Hf, Ti, Zr, Mg, Y, Ca, or Ce that is at least twice a concentration of of Hf, Ti, Zr, Mg. Y, Ca, or Ce in a dielectric material or layer 130 that is not high-K.

Substrate 110 may include multiple layers of conductors 150 and/or ground planes 140 in or separated by dielectric layers 130. Conductors 150 and ground planes 140 are of conductive materials, such as metals, that may have similar or differing compositions. In many embodiments, conductors 150 and ground planes 140 include copper. Conductors 150 may be metallization structures, such as copper traces, which couple and electrically connect to other metallization (or other conductive) structures, such as vias coupling conductors 150 in separate layers. Conductors 150 and vias may couple and electrically connect to input and output ports (I/Os). Ground planes 140 are layers of conductive material, such as sheets of copper (or another metal, etc.), and may include interruptions, e.g., to allow for conductors 150 or vias between ground planes 140 or conductors 150. In some embodiments, a ground plane 140 is coupled to a direct current (DC) power supply, but may be at small-signal ground, e.g., capacitively coupled to ground. Ground planes 140 may cover a substantial area of substrate 110, e.g., most of the area under an IC die 101 and beyond. In many embodiments, ground plane 140 spans most of the area of substrate 110

Substrate 110 may mechanically support and electrically couple one or more IC devices, such as dies 101. For example, IC die 101 may be coupled (e.g., soldered) to interconnect interfaces (such as contact pads over vias) through or in holes in ground plane 140. IC devices may couple to substrate 110 on an upper surface of substrate 110, or substrate 110 may have a well or cavity in which IC devices may be located. An upper surface of substrate 110 may be flush with the IC device(s), or IC device(s) might extend partially beyond the upper surface of substrate 110. At least one side of substrate 110 includes substrate interconnect interfaces for coupling (e.g., soldering, direct bonding, etc.) to one or more IC devices. The opposite side of substrate 110 may include similar interfaces or, e.g., copper pads for socketing or solder bumps for bonding to a host component, such as a PCB. Substrate 110 may be any host component with substrate interconnect interfaces, including an interposer, etc. Substrate 110 may couple to any other host component, such as another substrate.

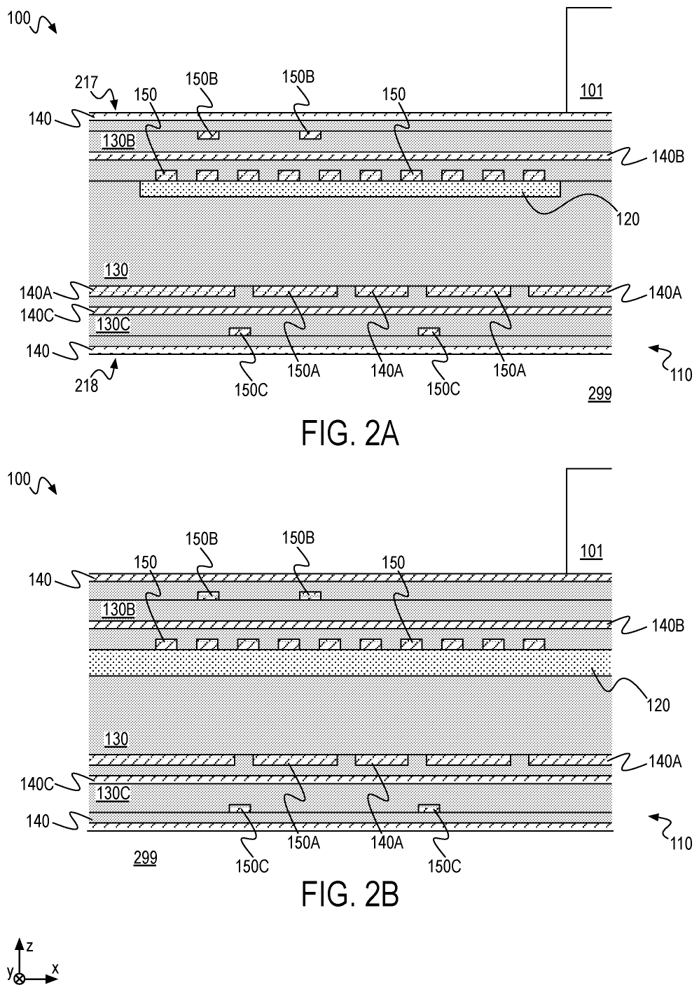

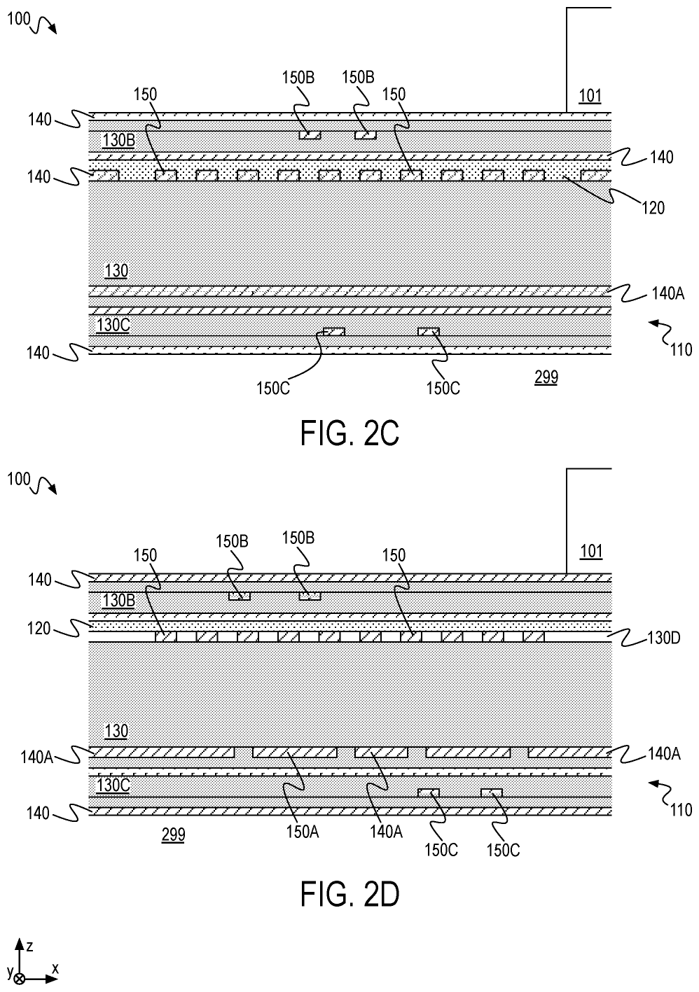

FIGS. 2A, 2B, 2C, and 2D illustrate substrates 110 in IC device 100 having conductors 150 adjacent dielectric layers 120, 130 and a ground plane 140 in a microstrip structure, in accordance with some embodiments. A microstrip structure using high-K and conventional, low-K dielectrics may be employed in various ways, and FIGS. 2A-2D show some advantageous embodiments.

FIG. 2A shows a microstrip structure similar to that shown in FIG. 1A with high-K dielectric layer 120 adjacent conductors 150 in a larger, multilayer substrate 110 coupled to IC die 101. A bus of conductors 150 are on high-K layer 120, within microstrip dielectric layer 130 and between microstrip dielectric layer 130 and high-K layer 120. Microstrip dielectric layer 130 is in contact with large core layer 130, e.g., on either side of high-K layer 120 and the bus of conductors 150. FIG. 2A illustrates how the high-K dielectric layer 120 and microstrip structure of FIG. 1A may be deployed to reduce a layer count in multilayer substrate 110. For example, substrate 110 may be an eight-layer replacement for a conventional 10-layer substrate 110, e.g., with two additional (now absent) ground planes 140 on either surface of large core layer 130. The two additional (now absent) ground planes 140 may have been deployed between a parallel bus of signal-carrying conductors 150 adjacent high-K dielectric layer 120 and power-carrying conductors 150A. High-K dielectric layer 120 has enabled high performance in substrate 110 with the microstrip structure, rather than a stripline structure with a higher layer count (with ground planes 140 and correspondingly more costs, complexity, manufacturing time, supply constraints, etc.).

IC device 100 includes ground plane 140A on a lower surface of large core layer 130, such that large core layer 130 separates high-K dielectric layer 120 and ground plane 140A. Large core layer 130 may have such a substantial thickness (and the distance between conductors 150 on high-K layer 120 is so great, e.g., relative to the distance between conductors 150 and ground plane 140B of the microstrip structure), such as in the example of FIG. 2A, that conductors 150 (on high-K layer 120) are not in a stripline structure with ground plane 140A. Ground plane 140C is below ground plane 140A, with ground planes 140A, 140C separated by a layer 130 (which may be of a same material as other layers 130) between planes 140A, 140C. In some embodiments, substrate 110 and device 100 include one, but not both, of ground planes 140A, 140C.

Ground plane 140A includes one or more conductors 150A, which are power lines coupled to a power supply (e.g., through a system substrate 299). Conductors 150A convey DC power and do not convey signals. Conductors 150A may be at small-signal ground, e.g., capacitively coupled to ground. Conductors 150A in a group of conductors 150A may each be separated from other conductors 150A by a portion of ground plane 140A at DC ground. IC device 100 includes a group of conductors 150B, 150C in balanced stripline configurations between ground planes 140. Ground plane 140B is between the group of conductors 150 (on high-K layer 120) and second group of conductors 150B. IC device 100 also includes a group of conductors 150C. Ground plane 140A is between large core layer 130 and the group of conductors 150C. Conductors 150 (such as conductors 150A, 150B, 150C) may be strategically routed to minimize interference between various signal-carrying conductors 150 (e.g., in parallel buses, on high-K layer 120).

Large core layer 130 may have a thickness significantly greater than the thicknesses of other dielectric layers 120, 130. For example, while large core layer 130 (at the center of substrate 110, between ground plane 140A and high-K layer 120) may have a thickness of 100 μm or more, other dielectric layers 130 (and high-K layer 120) may have a thickness of 10 μm or less. In some embodiments, large core layer 130 has a thickness of 150 μm or 200 μm or more. In some embodiments, other (non-core) dielectric layers 130 (and high-K layer 120) have a thickness of 15 μm or 20 μm. A large core layer 130 may support high-K layer 120 and enable manufacturing substrate 110 with a reduced layer count, e.g., by employing a microstrip structure with the ground planes required by a double-stripline structure.

Substrate 110 has ground planes 140 as upper and lower surfaces 217, 218, which may include interconnect interfaces (not shown), e.g., for coupling to other structures, such as IC dies 101, system substrate 299, etc. Substrate 299 may be a PCB, such as a motherboard. Soldermask (not shown) may be on surfaces 217, 218 and may have openings for the interconnect interfaces (which may be contact pads, bumps, etc.).

FIG. 2B illustrates a similar IC apparatus 100 as in the example of FIG. 2A with a bus of parallel conductors 150 at an interface of dielectric layers 120, 130 in a large, multilayer substrate 110. As in the example of FIG. 2A, substrate 110 includes upper and lower groups of conductors 150B, 150C in balanced stripline configurations between ground planes 140. Upper conductors 150B are between layers 130 (in layer 130B) and between ground plane 140B and upper ground plane 140 (on an upper surface of substrate 110). Lower conductors 150C are between layers 130 (in layer 130C) and between ground plane 140C and lower ground plane 140 (on a lower surface of substrate 110). And as in the example of FIG. 2A, a bus of parallel conductors 150 are on high-K dielectric layer 120 in a microstrip configuration with a microstrip dielectric layer 130 between ground plane 140B and conductors 150 on high-K layer 120. As before, large core layer 130 is between high-K layer 120 and the lower stripline configuration (and ground plane 140A above stripline conductors 150C). Notably, high-K layer 120 is between (and separates) microstrip dielectric layer 130 and core layer 130, and microstrip dielectric layer 130 does not contact large core layer 130.

High-K layer 120 may span the same lateral dimensions (and have a same lateral extent) as, e.g., large core layer 130. Such a structure may enable other manufacturing processes. In some embodiments, substrate 110 and high-K layer 120 are formed by depositing (or coupling) a high-K material over (or to) large core layer 130 using an additive process.

Substrate 110 has ground planes 140 as upper and lower surfaces 217, 218, which may include interconnect interfaces (not shown), e.g., for coupling to other structures, such as IC dies 101, system substrate 299, etc. Soldermask (not shown) may be on surfaces 217, 218 and may have openings for the interconnect interfaces.

Optional ground plane 140A may optionally include one or more conductors 150A, which may be DC power lines at small-signal ground.

FIG. 2C shows a similar IC apparatus 100 and substrate 110 as in the examples of FIGS. 2A and 2B with a bus of parallel conductors 150 at an interface of dielectric layers 120, 130 in a large, multilayer substrate 110. In the example of FIG. 2C, parallel conductors 150 are in high-K dielectric layer 120, and high-K dielectric layer 120 is between parallel conductors 150 and adjacent ground plane 140. The placement of high-K layer 120, e.g., between conductors 150 and ground plane 140, may influence both mutual and self capacitances Cₘ, Cₛ (and to different degrees) and so provide another degree of freedom for balancing various characteristics (e.g., FEXT, characteristic impedance Zₒ, etc.). This placement of high-K layer 120 may be achieved by any suitable means. Besides adding a degree of freedom to optimize system characteristics, a high-K layer 120 deposited, coupled, etc., over core layer 130 and a bus of parallel conductors 150 may beneficially simplify fabrication.

In some embodiments, as in the example of FIG. 2C, ground plane 140A, on an opposite side of core layer 130 may be substantially continuous layer of conductive material, e.g., a ground plane of copper.

FIG. 2D illustrates a similar IC apparatus 100 and substrate 110 as in the example of FIGS. 2A-2C. In the example of FIG. 2D, parallel conductors 150 are in dielectric layer 130D over core dielectric layer 130 with high-K dielectric layer 120 between conductors 150 and adjacent ground plane 140. Dielectric layer 130D may be the same, similar, or different dielectric material as that in other conventional or low dielectric layers 130. Dielectric layer 130D may be of a dielectric material used to fill in or build up dielectric over core dielectric layer 130. Dielectric layer 130D may bond core dielectric layer 130 and high-K dielectric layer 120. In some embodiments, dielectric layer 130D may be considered an interface layer between high-K dielectric layer 120 and core layer 130. In some embodiments, dielectric layer 130D may be over conductors 150 such that dielectric layer 130D separates conductors 150 and high-K dielectric layer 120. The higher permittivity of layer 120 between conductors 150 and ground plane 140 may still act to increase mutual capacitances and reduce (or otherwise modify) crosstalk, e.g., FEXT, etc.

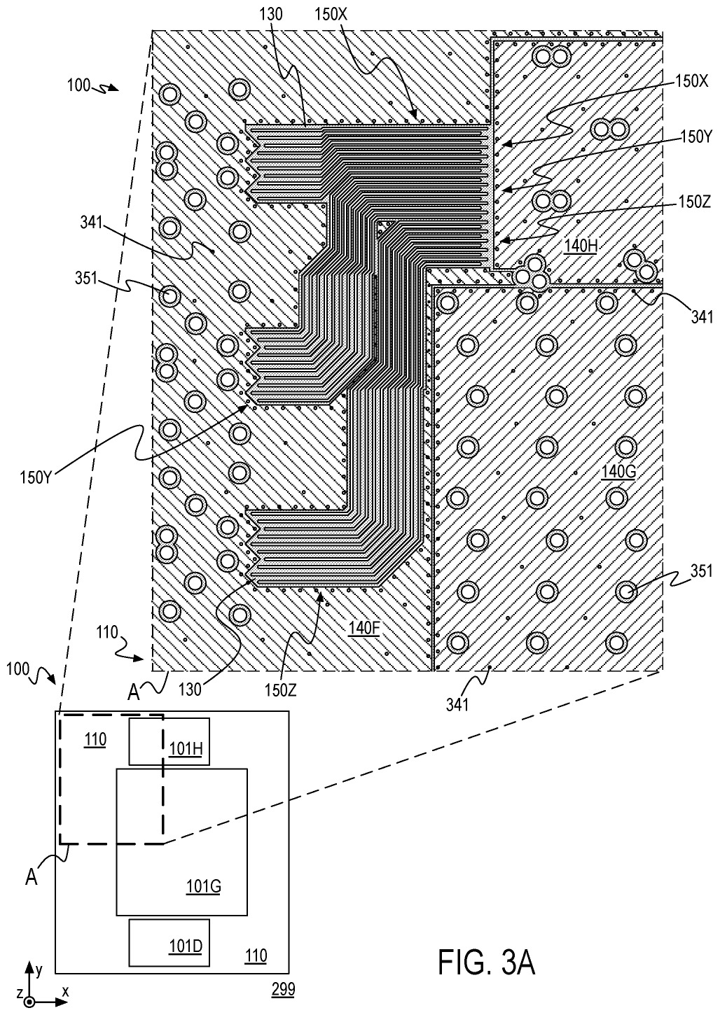

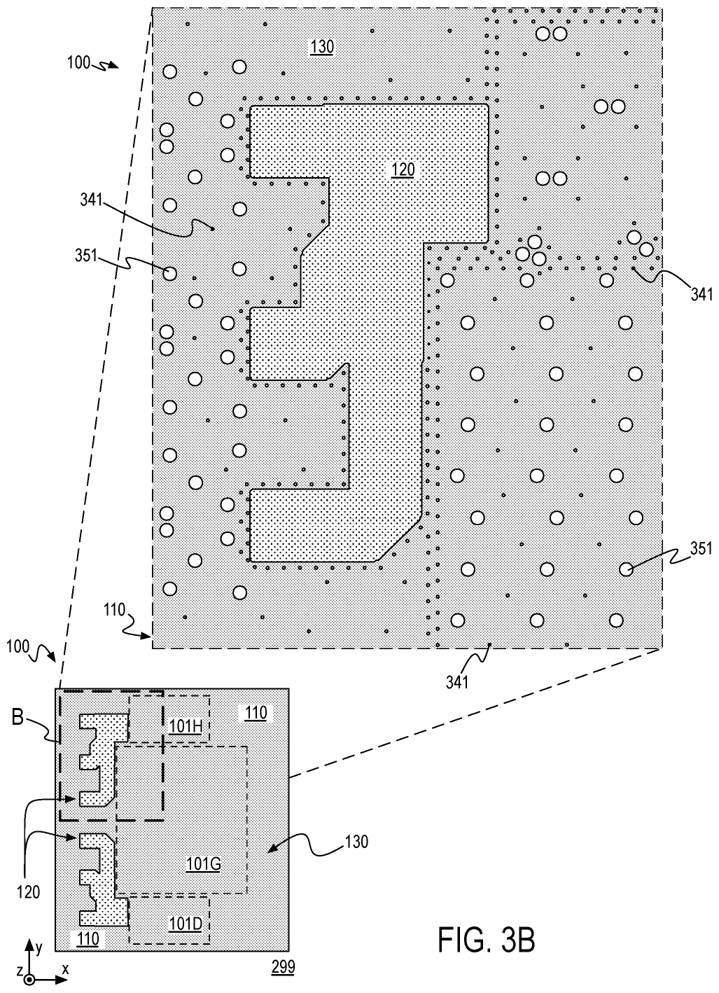

FIGS. 3A and 3B illustrate plan views of IC device 100, including adjacent layers of multilayer substrate 110 having groups (e.g., buses) of conductors 150X, 150Y, 150Z in dielectric layer 130 in cutouts of ground planes 140 and over dielectric layer 120, in accordance with some embodiments. FIG. 3A shows a magnified view or portion A of substrate 110 with conductors 150 and ground planes 140 separated by dielectric material in dielectric layer 130. View or portion A is shown in context situated in apparatus 100 and substrate 110, e.g., under and relative to IC devices, e.g., dies 101D, 101G, 101H. IC dies 101D, 101G, 101H may be IC dies or other devices, such as IC packages (each including at least one IC die). In some embodiments, IC dies 101D, 101G, 101H share a common ground plane 140. Buses of conductors 150X, 150Y, 150Z may include long coupled routing lengths X and high mutual inductances Lₘ, which may be necessary for DDR routing from I/Os under DDR IC die 101H (and DDR IC die 101D, outside of view or portion A) to package I/Os (e.g., solder bumps) along a left edge of substrate 110. Such DDR routing may be around a controller (e.g., central processing unit (CPU)) die 101G.

Conductors 150 run (in parallel with other conductors 150) through dielectric material in dielectric layer 130. Conductors 150 may be in contact with and directly over a high-K dielectric material in high-K dielectric layer 120. In some embodiments, conductors 150X, 150Y, 150Z are in high-K dielectric layer 120 in cutouts of ground plane 140F.

Conductors 150 may be in a layer with one or more ground planes 140. Multiple ground planes 140 may be partitioned (e.g., dedicated) ground planes 140 on a same layer. For example, ground plane 140H may be under IC die 101H and separated from ground plane 140G under IC die 101G. Ground plane 140D (not shown) may be under IC die 101D and separated from ground planes 140B, 140C. Ground planes 140D, 140G, 140H may be separated from ground plane 140F, which may be in the same layer and extend over most of the footprint of substrate 110. Ground planes 140 may be stitched to grounds, e.g., ground planes 140, in other layers and at other levels by ground vias 341, for example, along the edges of partitioned ground planes 140D, 140G, 140H. (The outlines of ground vias 341 are shown for illustrative purposes, but ground vias 341 may be continuous with ground planes 140 at the level shown in view or portion A. Ground vias 341 may extend above and/or below ground planes 140.)

Signal vias 351 extend through ground planes 140 (and dielectric layer 130), e.g., to couple to interconnect interfaces (such as contact pads) of various IC dies 101. Signal vias 351 may transmit signals to or from inputs and/or output ports (I/Os; not shown), e.g., above or below ground plane 140A along the left edge of (view or portion A and) substrate 110. Conductors 150X, 150Y, 150Z are configured to convey signals from IC die 101C to various I/O ports along the left edge of substrate 110. Vias 341, 351 are shown with circular cross-sections, but vias 341, 351 may have other (e.g., rectangular) cross-sections. Vias 341, 351 may be solid (e.g., filled) or other structures (e.g., plated, tubular, etc.).

FIG. 3B illustrate plan views of the IC device 100 of FIG. 3A, including a portion B of dielectric layers 120, 130 of multilayer substrate 110 below the portion A in the layer of FIG. 3A, in accordance with some embodiments. FIG. 3B shows a magnified view or portion B of substrate 110 under conductors 150 and ground planes 140 of FIG. 3A. FIG. 3B also shows view or portion B situated in apparatus 100 and substrate 110, e.g., under and relative to IC dies 101D, 101G, 101H.

High-K dielectric layer 120 is in dielectric layer 130, e.g., in a cavity within dielectric layer 130. High-K dielectric layer 120 is in contact with and directly under conductors 150X, 150Y, 150Z. FIG. 3B shows a similar high-K dielectric layer 120 in dielectric layer 130 in contact with and directly under conductors 150 configured to convey signals from IC die 101D to various I/O ports along the left edge of substrate 110.

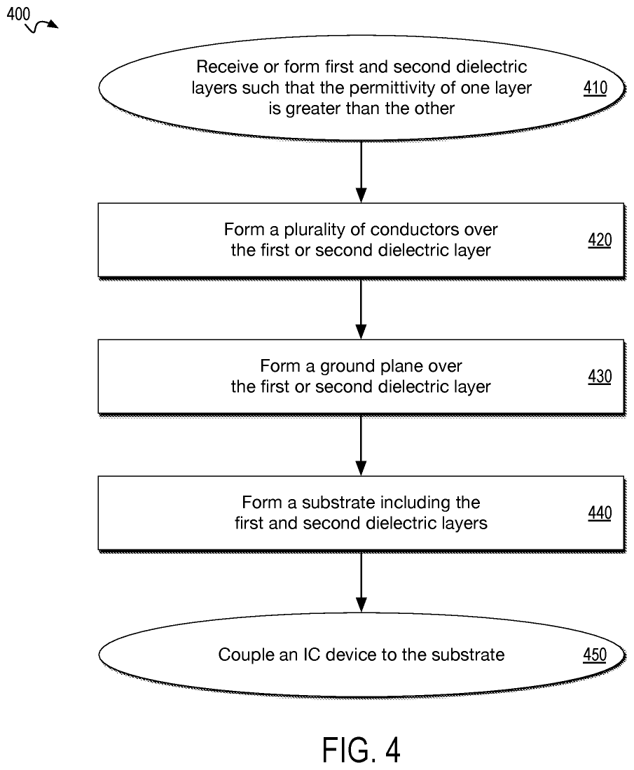

FIG. 4 is a flow chart of methods 400 for forming a substrate with conductors along an interface of lower- and higher-permittivity dielectric layers, in accordance with some embodiments. Methods 400 include operations 410-450. Some operations shown in FIG. 4 are optional. Additional operations may be included. FIG. 4 shows an example sequence, but the operations can be done in other orders as well, and some operations may be omitted. Some operations can also be performed multiple times before other operations are performed. For example, multiple dielectric layers may be formed over (or coupled to) a substrate. Multiple groups of conductors may be formed (e.g., deposited) over one or more dielectric layers. Some operations may be included within other operations so that the number of operations illustrated FIG. 4 is not a limitation of the methods 400.

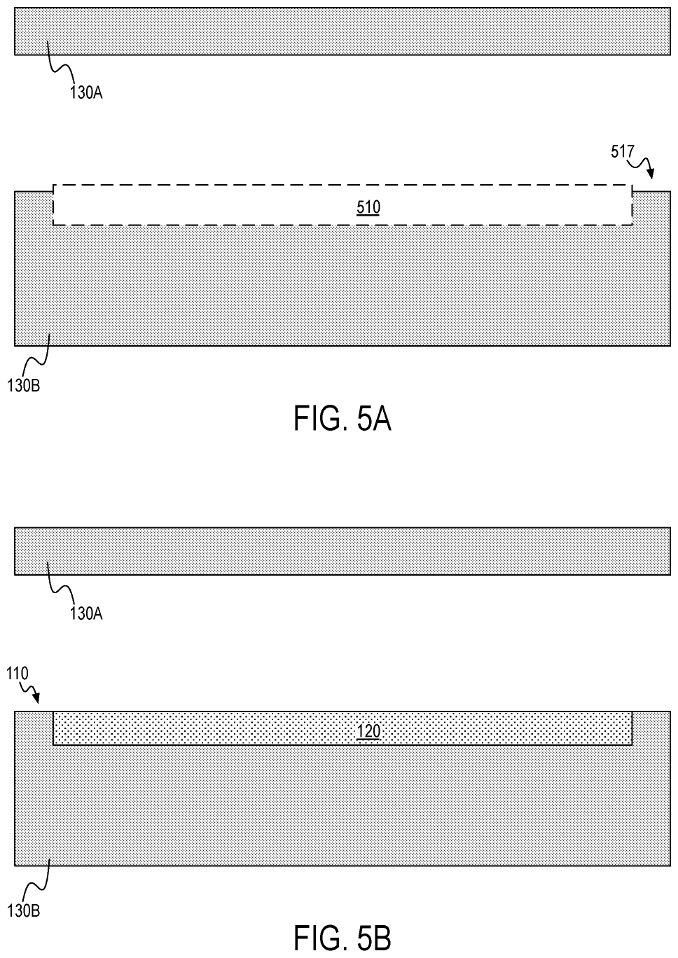

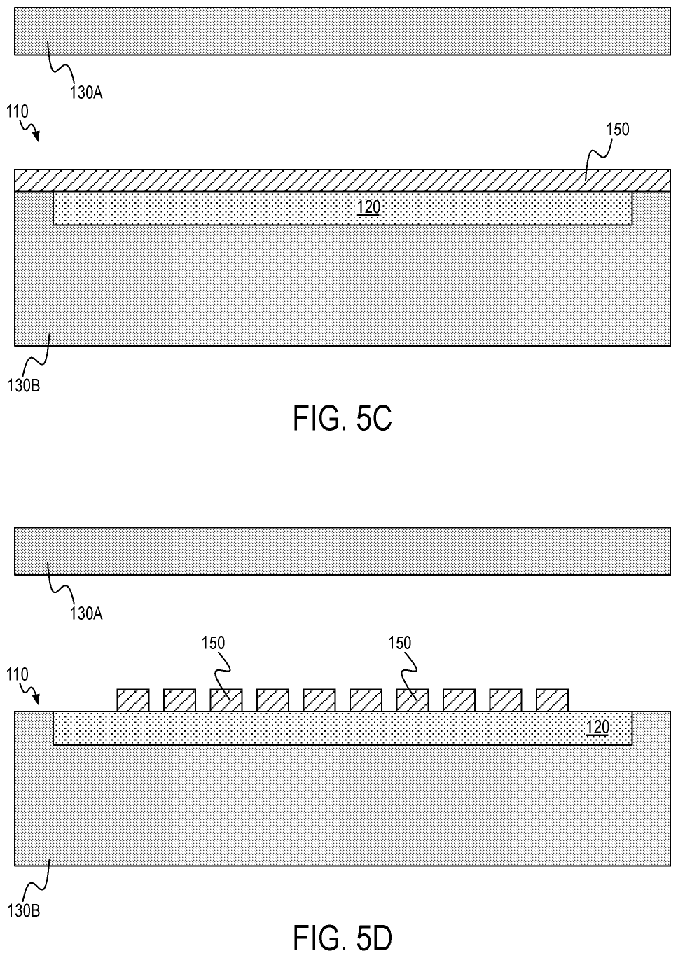

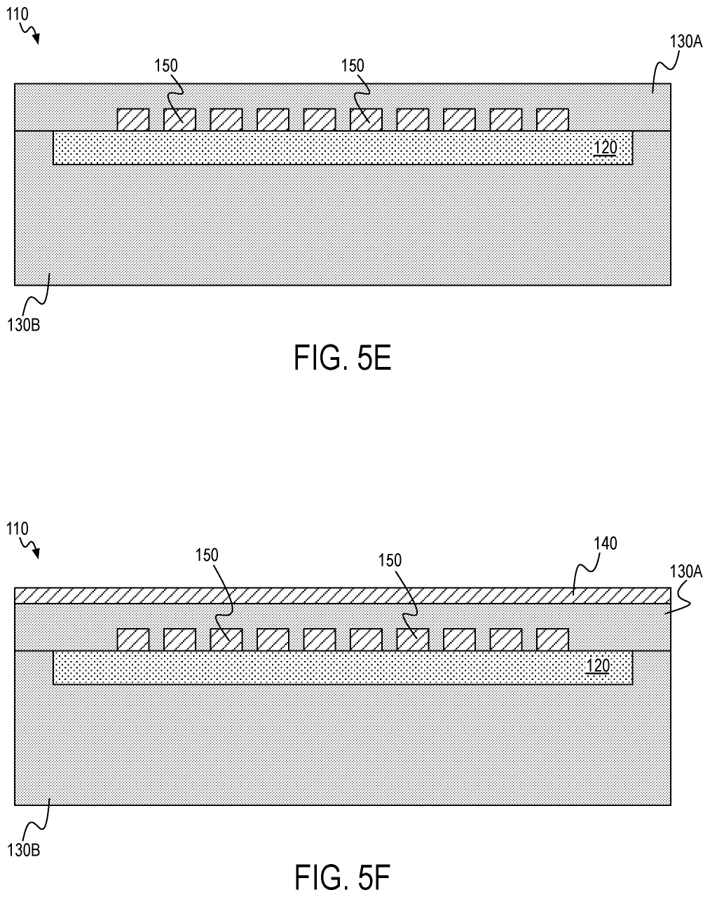

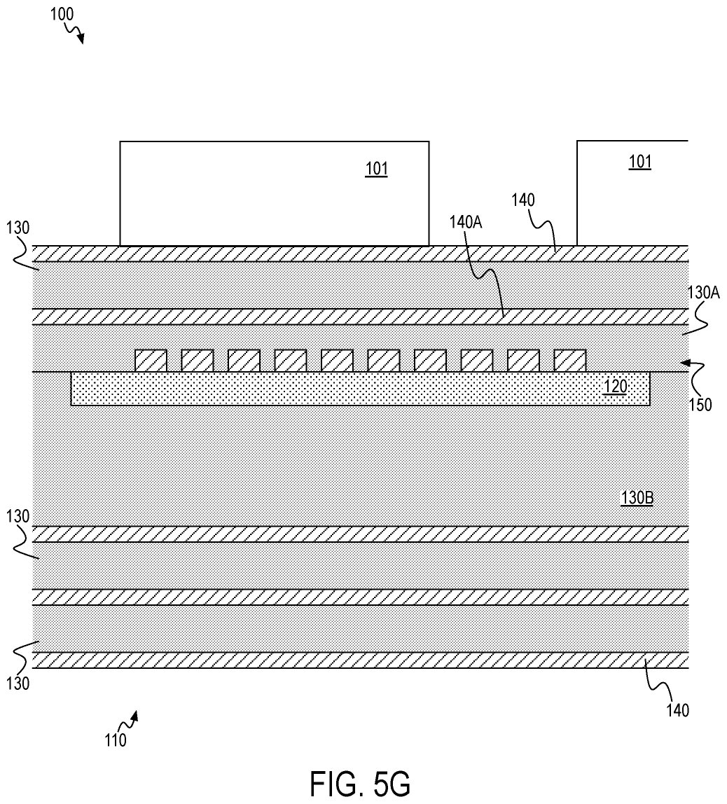

FIGS. 5A, 5B, 5C, 5D, 5E, 5F, and 5G illustrate cross-sectional profile views of substrate 110 with high-K dielectric layer 120 adjacent conductors 150 and conventional dielectric layers 130, at various stages of manufacture, in accordance with some embodiments.

Methods 400 begin at operation 410 with receiving or forming at least two dielectric layers with at least one of the layers having a relative permittivity greater than a relative permittivity of the other dielectric layer. Conventional materials may be used. For example, various materials are employed in the manufacture of IC (and other) substrates, and those materials may have a range of relative permittivities. A low-permittivity material, such as polytetrafluoroethylene (PTFE) for use in low-loss substrates, may be deployed in a lower-permittivity first layer, and a higher-permittivity material may be deployed in a higher-permittivity second layer. The higher-permittivity material (in the second layer) may be a conventional material (such as PTFE with an interspersed ceramic material) or may be purpose-built for the higher-permittivity second layer (e.g., by interspersing the ceramic material in a base material at a desired concentration).

In many embodiments, multiple first dielectric layers (e.g., five, seven, 11, 19, etc.) will be formed or received for assembly into a substrate with layers of conductors on one or both sides of each dielectric layer. In some such embodiments, most dielectric layers (e.g., all but one) will have a same or similar permittivity that is low relative to a single layer with a higher permittivity. In many embodiments, one or more of the lower-permittivity dielectric layers is a core dielectric layer, and others of the lower-permittivity dielectric layers are build-up (e.g., “prepreg”) dielectric layers, which may be impregnated with a not-yet-cured resin.

At least one second dielectric layer (with a higher permittivity than the one or more first layers) will be employed in the multi-layer substrate. In many embodiments, the second dielectric layer(s) will be deployed in or over a first, core layer, which may have a greater thickness than the second dielectric layer(s). The second dielectric layer(s) may be used strategically, only in certain locations, to maximize or balance the benefit of reduced crosstalk with the costs of manufacture (e.g., monetary, time, or other).

In some embodiments, both first and second layers may be formed and/or received independently, e.g., laminates of different materials. In other embodiments, one or both layers are formed or built up over another layer, which may be a substrate or core layer for building up multiple layers on one or both sides of the substrate. In some such embodiments, the higher-permittivity second layer is formed in or over a lower-permittivity layer, which may be the lower-permittivity first layer or another lower-permittivity layer (which may be the same, similar, or otherwise related to the first layer). For example, the higher-permittivity second layer may be formed by depositing a higher-permittivity material (such as a composite of ceramic particles in a polymer) over a lower-permittivity core layer. The higher-permittivity second layer may be deposited over the entirety of one surface of the lower-permittivity layer. In some embodiments, a cavity is formed in the lower-permittivity layer, and the higher-permittivity dielectric material is formed in the cavity. The cavity may be formed by any suitable means, e.g., by drilling and/or milling, or by employing a router (or similar tool). The deposition may also be done however is necessary or convenient. In some embodiments, a cavity is filled (or even over-filled) with a viscous composite, which may then be cured. In some embodiments, a rigid or semi-rigid laminate (e.g., of a higher-permittivity material) of appropriate size is contacted to or in a lower-permittivity laminate. After deposition, a planarization operation may be utilized to ensure the higher-permittivity layer (or the surface having both lower- and higher-permittivity materials) is sufficiently flat. Hollowing out a cavity and depositing a higher-permittivity material in the cavity may allow for deploying only minimal amounts of higher-permittivity material and/or only in precise locations, e.g., while otherwise using only conventional materials. For example, conventional laminates may be used with a higher-permittivity dielectric layer on a surface of a conventional laminate only locally adjacent to one or more signal-carrying conductors (such as a DDR bus). In embodiments with a dielectric layer (such as a higher-permittivity layer) in a core or other laminate layer, the other dielectric layer (such as a lower-permittivity layer) may be formed as a build-up layer over the laminate layer when a group of dielectric layers are assembled in a stack. For example, a dielectric layer may be a resin-saturated, fiberglass weave (e.g., a “prepreg” layer) interleaved between laminate layers (or between a laminate layer and a conductive layer) during lamination press.

FIG. 5A shows lower-permittivity first layer 130A (e.g., a standard or lower-permittivity laminate) and lower-permittivity core layer 130B with a hollow, opening, or cavity 510 in an upper surface 517 of core layer 130B. Cavity 510 may be absent over much of core layer 130B and surface 517. Cavity 510 may be present only in locations meant for signal-carrying conductors (or certain signal-carrying conductors, such as conductors for high-frequency signals).

FIG. 5B illustrates higher-permittivity second layer 120 over lower-permittivity core layer 130B, e.g., after a higher-permittivity material has been deposited into cavity 510 at operation 410. In some embodiments, layers 120, 130B have the same lateral dimensions.

Returning to FIG. 4, methods 400 continue with forming a plurality of conductors on the first or second dielectric layer at operation 420. Any suitable means and materials may be employed. For example, any suitable conductive material (such as a metal) may be deployed. In many embodiments, copper traces are formed over one of the lower- or higher-permittivity layers. Other metals (or other materials) may be employed. The conductors may be formed by any of various means, including additive or subtractive means, conventional or otherwise. In some embodiments, a conductive film (such as a copper foil) is formed over a significant portion (e.g., all) of one or more surfaces of a dielectric layer, and conductive traces are formed subtractively by removing conductive material between the trace locations. For example, a photoresist may be applied over the film, exposed in the desired pattern, and removed between trace locations before etching away unmasked conductive material. For plating operations, foil may act as a seed layer before plating, e.g., to add further thickness of conductive material. In other embodiments, conductive traces are formed additively by deposition of (e.g., plating) a conductive material (such as copper) onto one or more surfaces of a dielectric layer in the desired pattern. Again, a photoresist mask may be patterned over a dielectric layer. In some embodiments, the photoresist covers much of the dielectric layer, and the conductive material is deposited in openings in the photoresist mask. Electroplating and electroless plating (e.g., electroless copper plating) may be employed. In some embodiments, at least some operations are performed on opposite surfaces of a dielectric layer (such as a core or other laminate layer) concurrently, e.g., etching of copper foil(s). In some embodiments, multiple means of patterning and/or forming conductors are used, e.g., with one means used for core or laminate layers, and another means used for other built-up dielectric layers.

FIG. 5C shows substrate 110 with at least a single conductor 150 (e.g., a copper foil) over higher- and lower-permittivity layers 120, 130B, such as a laminate after a conductive material has been deposited over layers 120, 130B at operation 420.

FIG. 5D illustrates substrate 110 with a group of parallel conductors 150 (such as in a bus) over higher- and lower-permittivity layers 120, 130B, for example, following an operation 420.

Returning to FIG. 4, methods 400 continue at operation 430 by forming a ground plane over the first or second dielectric layer. Forming a ground plane (e.g., a conductive layer) over one of the dielectric layers may be similar to a portion of 420, which (in some embodiments) may substractively form conductors from a layer of conductive material over one of the dielectric layers. In some embodiments, a ground plane is formed over a dielectric layer before the first and second dielectric layers are bonded together into a stack of layers in a substrate. In some embodiments, a ground plane is formed over a dielectric layer after the first and second dielectric layers have been formed into a stack of layers, e.g., after the first and second dielectric layers have been contacted together and bonded. In some embodiments, a ground plane is formed over a dielectric layer concurrently with the first and second dielectric layers being formed into a stack of layers, e.g., during a lamination press.

Methods 400 continue by forming a substrate including a stack of the first and second dielectric layers at operation 440. The substrate includes multiple dielectric layers, a group of conductors at an interface of lower- and higher-permittivity dielectric layers, and one or more conductive layers (as ground planes) such that a ground plane is separated from the group of conductors by either of the lower- and higher-permittivity dielectric layers. In some embodiments, forming a substrate includes coupling together dielectric layers in a stack. In some embodiments, forming a substrate includes forming one or more dielectric layers over a core layer, e.g., building up a dielectric layer over existing dielectric layer. For example, a core layer (or laminate) of dielectric may have patterned conductors (or a substantially continuous conductive layer, or a conductive layer with patterned conductors in non-continuous regions), and dielectric layers may be built up in one or both directions from the core layer (e.g., on front and back sides of the core layer). Multiple laminate dielectric layers (e.g., with substantially continuous and/or patterned conductors one either or both sides) may be arranged in a stack and bonded together. In many embodiments, the substrate is formed from a stack of laminate dielectric layers bonded together with resin-saturated (e.g., prepreg) dielectric layers between the laminates. In such embodiments, the stack may be pressed together at temperature to melt resin and perform the bonding. Conductive layers, such as of copper, may be included at various levels of the stack, for example, at the upper and lower surfaces. As an example, in some embodiments, the substrate is formed by coupling a lower-permittivity (first) layer of prepreg between multiple laminate layers, where a thin, higher-permittivity (second) layer is in a cavity of a lower-permittivity (third) core layer, and multiple conductors (such as a parallel bus) are on the second layer between the first and second layers. The first (prepreg) layer may be between (and separating) a conductive layer (e.g., a copper ground plane) on a laminate layer and the bus of conductors on the second layer. In many embodiments, the substrate includes multiple conductive layers (e.g., an even number of layers, such as eight, ten, 12, or 20).

FIG. 5E shows substrate 110 with a stack of layers 120, 130, including a bus of parallel conductors 150 between lower-permittivity layer 130A and higher-permittivity layer 120, e.g., following an operation 440. For example, higher-permittivity layer 120 may be within a lower-permittivity core layer 130B, and lower-permittivity layer 130A may be a laminate layer joined to core layers 120, 130B. In some embodiments, lower-permittivity layer 130A is a prepreg layer over core layers 120, 130B. In some such embodiments, lower-permittivity layer 130A includes cured resin over layer 120, e.g., between conductors 150.

FIG. 5F illustrates substrate 110 with a stack of layers 120, 130, a bus of parallel conductors 150, and ground plane 140 separated from conductors 150 by lower-permittivity dielectric layer 130A, for example, after an operation 440. Ground plane 140 may have been formed by any suitable means, such as by an operation previously described. In some embodiments, ground plane 140 is a conductive layer formed by electroless copper plating on a surface of build-up dielectric layer 130A. In some embodiments, ground plane 140 is a conductive layer on a lower surface of a laminate dielectric layer (not shown), over prepreg layer 130A in a stack of layers 130. Substrate 110 may include multiple layers 130, and layer 120 may be deployed in a single layer (e.g., in multiple regions on a surface of layer 130B, under buses of conductors 150).

Returning to FIG. 4, methods 400 may continue with coupling an IC device to the substrate at operation 450. For example, the IC device may be an IC die, which may be soldered to the substrate. Multiple IC dies (or other IC devices) may be coupled to the substrate and by any suitable means. The IC devices may be coupled to interconnect interfaces (such as contact pads) patterned in a conductive layer (e.g., ground plane) on a substrate surface.

Other operations may be performed at various stages before, after, or concurrently with the operations described in methods 400, as is convention. For example, electrical connections between layers may be made at one or more times. In some embodiments, via holes, e.g., through holes, are drilled through the substrate. Via holes may be plated, e.g., as described (or otherwise). In some embodiments, via holes are filled solid (e.g., with copper). In some embodiments, via holes, e.g., buried holes, are formed in dielectric layers before joining a stack of layers into a substrate.

FIG. 5G shows IC device, for example, after an operation 450. A bus of conductors 150 are over high-permittivity dielectric layer 120 in low-permittivity core dielectric layer 130B. Conductors 150 are between high-permittivity dielectric layer 120 and low-permittivity prepreg layer 130A. Low-permittivity dielectric layer 130A is between conductors 150 and ground plane 140A. Upper and lower low-permittivity laminate layers 130 are clad above and below by ground planes 140, and prepreg low-permittivity dielectric layers 130, 130A are between core dielectric layer 130B and upper and lower low-permittivity layers 130 (with ground planes 140 between layers 130).

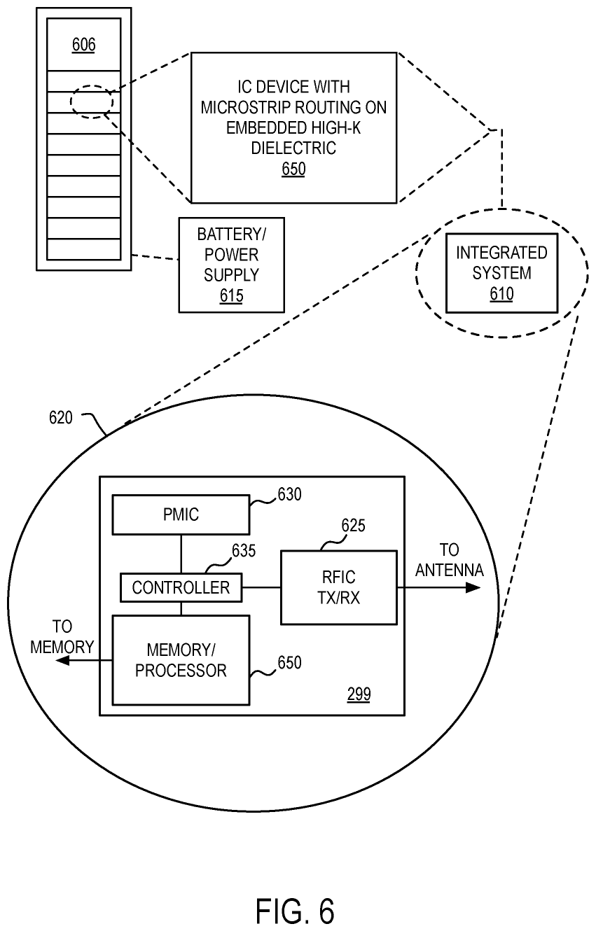

FIG. 6 illustrates a diagram of an example data server machine 606 employing an IC device having signal lines between higher- and lower-permittivity dielectric layers in a microstrip structure, in accordance with some embodiments. In other embodiments, an IC device having signal lines between higher- and lower-permittivity dielectric layers in a microstrip structure is included in a mobile laptop application. Such a device, as described herein, may be deployed in yet other applications. Server machine 606 may be any commercial server, for example, including any number of high-performance computing platforms disposed within a rack and networked together for electronic data processing, which in the exemplary embodiment includes one or more devices 650 with signal lines between higher and lower-permittivity dielectric layers in a microstrip structure.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having signal lines between higher and lower-permittivity dielectric layers in a microstrip structure, as discussed herein. Device 650 may be further coupled to (e.g., communicatively coupled to) a board, an interposer, or a substrate 299 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments. RFIC 625, PMIC 630, controller 635, and device 650 include signal lines between higher and lower-permittivity dielectric layers in a microstrip structure.

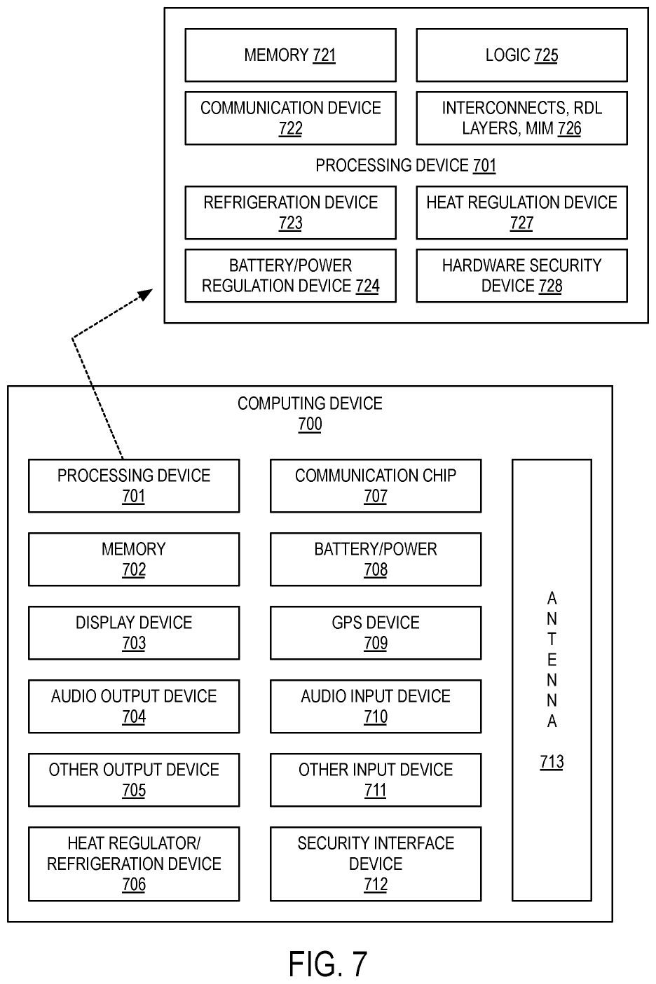

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) or spin transfer torque magnetic random-access memory (STT-MRAM).

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a substrate, and an IC die on the substrate, wherein the substrate includes a first dielectric layer, a second dielectric layer, and a third dielectric layer, wherein the second dielectric layer is between the first and third dielectric layers, and the first dielectric layer has a first relative permittivity less than a second relative permittivity of the second dielectric layer, and the second relative permittivity is greater than a third relative permittivity of the third dielectric layer, a plurality of conductors at an interface of the first and second dielectric layers, wherein the second dielectric layer is between the plurality of conductors and the third dielectric layer, and a conductive layer adjacent the first and second dielectric layers, wherein one of the first and second dielectric layers is between the conductive layer and the other of the first and second dielectric layers.

In one or more second embodiments, further to the first embodiments, the plurality of conductors includes four or more lines substantially parallel to each other.

In one or more third embodiments, further to the first or second embodiments, the second dielectric layer is separated from the conductive layer by the first dielectric layer.

In one or more fourth embodiments, further to the first through third embodiments, the plurality of conductors is within the first dielectric layer and in contact with the second dielectric layer.

In one or more fifth embodiments, further to the first through fourth embodiments, the second dielectric layer includes first and second surfaces, the first surface is in contact with a third surface of the third dielectric layer, and the second surface is substantially coplanar with a fourth surface of the third dielectric layer.

In one or more sixth embodiments, further to the first through fifth embodiments, the third dielectric layer has a relative permittivity approximately equal to a relative permittivity of the first dielectric layer.

In one or more seventh embodiments, further to the first through sixth embodiments, the conductive layer is a first conductive layer, and further including a second conductive layer, wherein the third dielectric layer separates the second dielectric layer and the second conductive layer.

In one or more eighth embodiments, further to the first through seventh embodiments, the plurality of conductors is a plurality of first conductors, and further including a plurality of second conductors, wherein the first conductive layer is between the plurality of first conductors and the plurality of second conductors.

In one or more ninth embodiments, further to the first through eighth embodiments, the apparatus also includes a plurality of third conductors, and the second conductive layer is between the third dielectric layer and the plurality of third conductors.

In one or more tenth embodiments, further to the first through ninth embodiments, the second conductive layer includes a conductor coupled to a power supply.

In one or more eleventh embodiments, further to the first through tenth embodiments, the IC die is coupled to a power supply through the substrate.

In one or more twelfth embodiments, an apparatus includes a first ground plane at a first surface of a substrate and an adjacent second ground plane, a third ground plane at a second surface of the substrate and an adjacent fourth ground plane, wherein first, second, and third dielectric layers are between the second and third ground planes, the first dielectric layer is between the second and third dielectric layers, a first relative permittivity of the first dielectric layer is greater than both a second relative permittivity of the second dielectric layer and a third relative permittivity of the third dielectric layer, and a plurality of conductors between the first and second dielectric layers.

In one or more thirteenth embodiments, further to the twelfth embodiments, the apparatus also includes an IC die, and the IC die is coupled to the substrate at the first or second surface.

In one or more fourteenth embodiments, further to the twelfth or thirteenth embodiments, the plurality of conductors include four or more lines substantially parallel to each other.

In one or more fifteenth embodiments, further to the twelfth through fourteenth embodiments, the second dielectric layer is in contact with the third dielectric layer.

In one or more sixteenth embodiments, further to the twelfth through fifteenth embodiments, the plurality of conductors is plurality of first conductors, and further including a plurality of second conductors between the first and second ground planes or the third and fourth ground planes.

In one or more seventeenth embodiments, a method includes receiving or forming a first dielectric layer and a second dielectric layer, wherein a relative permittivity of the second dielectric layer is greater than a relative permittivity of the first dielectric layer, forming a plurality of conductors on the first or second dielectric layer, forming a ground plane over the first or second dielectric layer, and forming a substrate including a stack of the first and second dielectric layers, wherein the plurality of conductors is at an interface of the first and second dielectric layers and the plurality of conductors is separated from the ground plane by the first or second dielectric layer.

In one or more eighteenth embodiments, further to the seventeenth embodiments, forming the second dielectric layer includes forming a dielectric material over a third dielectric layer.

In one or more nineteenth embodiments, further to the seventeenth or eighteenth embodiments, forming the dielectric material over the third dielectric layer includes forming a cavity in the third dielectric layer and depositing the dielectric material in the cavity, the second and third dielectric layers have substantially coplanar upper surfaces, and forming the substrate includes coupling the first and third dielectric layers.

In one or more twentieth embodiments, further to the seventeenth through nineteenth embodiments, the method also includes coupling an IC die to the substrate.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a substrate; and
an integrated circuit (IC) die on the substrate, wherein the substrate comprises:
a first dielectric layer, a second dielectric layer, and a third dielectric layer, wherein the second dielectric layer is between the first and third dielectric layers, and the second layer has at least twice as much hafnium, titanium, or zirconium as the first dielectric layer or the third dielectric layer;
a plurality of conductors at an interface of the first and second dielectric layers, wherein the second dielectric layer is between the plurality of conductors and the third dielectric layer; and
a conductive layer adjacent the first and second dielectric layers, wherein one of the first and second dielectric layers is between the conductive layer and the other of the first and second dielectric layers.

2. The apparatus of claim 1, wherein the plurality of conductors comprises four or more lines substantially parallel to each other.

3. The apparatus of claim 1, wherein the second dielectric layer is separated from the conductive layer by the first dielectric layer.

4. The apparatus of claim 1, wherein the plurality of conductors is within the first dielectric layer and in contact with the second dielectric layer.

5. The apparatus of claim 1, wherein the second dielectric layer comprises first and second surfaces, the first surface is in contact with a third surface of the third dielectric layer, and the second surface is substantially coplanar with a fourth surface of the third dielectric layer.

6. The apparatus of claim 1, wherein the third dielectric layer has a relative permittivity approximately equal to a relative permittivity of the first dielectric layer.

7. The apparatus of claim 1, wherein the conductive layer is a first conductive layer, and further comprising a second conductive layer, wherein the third dielectric layer separates the second dielectric layer and the second conductive layer.

8. The apparatus of claim 7, wherein the plurality of conductors is a plurality of first conductors, and further comprising a plurality of second conductors, wherein the first conductive layer is between the plurality of first conductors and the plurality of second conductors.

9. The apparatus of claim 8, further comprising a plurality of third conductors, wherein the second conductive layer is between the third dielectric layer and the plurality of third conductors.

10. The apparatus of claim 7, wherein the second conductive layer comprises a conductor coupled to a power supply.

11. The apparatus of claim 1, wherein the IC die is coupled to a power supply through the substrate.

12. An apparatus, comprising:
a first ground plane at a first surface of a substrate and an adjacent second ground plane;
a third ground plane at a second surface of the substrate and an adjacent fourth ground plane, wherein first, second, and third dielectric layers are between the second and third ground planes, the first dielectric layer is between the second and third dielectric layers, a first relative permittivity of the first dielectric layer is greater than both a second relative permittivity of the second dielectric layer and a third relative permittivity of the third dielectric layer; and
a plurality of conductors between the first and second dielectric layers.

13. The apparatus of claim 12, further comprising an integrated circuit (IC) die, wherein the IC die is coupled to the substrate at the first or second surface.

14. The apparatus of claim 13, wherein the plurality of conductors comprise four or more lines substantially parallel to each other.

15. The apparatus of claim 14, wherein the second dielectric layer is in contact with the third dielectric layer.

16. The apparatus of claim 15, wherein the plurality of conductors is plurality of first conductors, and further comprising a plurality of second conductors between the first and second ground planes or the third and fourth ground planes.

17. A method, comprising:
receiving or forming a first dielectric layer and a second dielectric layer, wherein a relative permittivity of the second dielectric layer is greater than a relative permittivity of the first dielectric layer;
forming a plurality of conductors on the first or second dielectric layer;
forming a ground plane over the first or second dielectric layer; and
forming a substrate comprising a stack of the first and second dielectric layers, wherein the plurality of conductors is at an interface of the first and second dielectric layers and the plurality of conductors is separated from the ground plane by the first or second dielectric layer.

18. The method of claim 17, wherein forming the second dielectric layer comprises forming a dielectric material over a third dielectric layer.

19. The method of claim 18, wherein forming the dielectric material over the third dielectric layer comprises forming a cavity in the third dielectric layer and depositing the dielectric material in the cavity, the second and third dielectric layers have substantially coplanar upper surfaces, and forming the substrate comprises coupling the first and third dielectric layers.

20. The method of claim 17, further comprising coupling an integrated circuit (IC) die to the substrate.
